(19) United States
(12) Patent Application Publication
(10) Pub. No.: US 2006/0258186 A1
(43) Pub. Date: Nov. 16, 2006

(54) Electric distribution box

(75) Inventors: Masatoshi Egawa, Kakegawa-shi (JP); Takuya Nakayama, Kakegawa-shi (JP); Yumi Sekine, Kakegawa-shi (JP); Maki Sugiura, Kakegawa-shi (JP)

Correspondence Address: SUGHRUE MION, PLLC, 2100 PENNSYLVANIA AVENUE, N.W., SUITE 800, WASHINGTON, DC, 20037, US

(73) Assignee: YAZAKI CORPORATION

(21) Appl. No.: 11/415,141

(22) Filed: May 2, 2006

(30) Foreign Application Priority Data
May 13, 2005 (JP) P2005-141583

(51) Int. Cl. H05K 1/00

(52) U.S. Cl. 439/76.2

(57) ABSTRACT

An electric distribution box includes a first cassette block that includes a flat face having a first long side and a second short side, and provided with a first electric parts, a second cassette block that includes a flat face having a second long side and a second short side, and provided with a second electric parts, and a bus bar that connects a terminal of the first electric parts to a terminal of the second electric parts. The first cassette block is arranged with the second cassette block so that the first long side of the first cassette block and the second long side of the second cassette block are disposed in parallel and opposed to each other. The bus bar is disposed along outer surfaces of the first and second cassette blocks.

### BACKGROUND OF THE INVENTION

This invention relates to an electric distribution box for mounting on an automobile serving as a mobile body.

Generally, various electronic equipments, including lamps such as headlamps and tail lamps and motors such as a starter motor and an air-conditioner motor, are mounted on an automobile serving as a mobile body.

In order to supply electric power to the above various electronic equipments, a junction block, serving as a power distribution box, has been located at a suitable portion of the automobile. The junction block is formed by combining various electric circuit units of many fuses, relays, etc., together.

The junction block includes fuses, relays, bus bars, etc., and therefore is often called a fuse block or a relay box, or generically called an electric distribution box. In the present specification, the fuse block, the relay box and the junction block will hereafter be generically called an electric distribution box.

An electric distribution box includes a box body forming a shell, fuse blocks serving as a pair of cassette blocks, and wiring boards. The box body receives the pair of fuse blocks therein. The fuse block includes a block body, and a plurality of fuses (electric parts).

The block body has, for example, a rectangular shape when viewed from the top, and its width in one direction is longer than its width in another direction perpendicular to the one direction. A plurality of mounting portions for mounting the fuses thereon are provided at an upper surface of the block body. Connectors are provided at a lower surface of the block body, and connectors of wire harnesses are fitted respectively into these connectors. The plurality of fuses are mounted on the block body in such a manner that theses fuses are juxtaposed in a longitudinal direction of the block body. The fuse blocks are mounted in the box body.

The wire harness comprises a plurality of wires, and connectors mounted at end portions of the wires. The connectors are fitted to connectors of various electronic equipments and a power source (such as a battery), mounted on the automobile, and the connectors provided at the block bodies of the fuse blocks.

The wiring board is received in the block body of the fuse block, and includes bus bars which connect one terminals of the plurality of fuses (mounted on the fuse block) together, and also connect terminals of the connectors to the terminals of the fuses in a predetermined pattern.

In order to connect the one terminals of the fuses of the two fuse blocks together, the pair of fuse blocks are mounted in the electric distribution box in such a manner that the longitudinal axes of the two fuse blocks are disposed generally on a common line, and the one terminals are connected together.

The electric distribution box is assembled in the following manner. First, the wiring boards are received in the respective block bodies, and the desired fuses are mounted on the block bodies. Further, the block bodies, that is, the fuse blocks, are connected together in the above-mentioned manner, and these fuse blocks are mounted in the box body. Then, the connectors of the wire harnesses are fitted to the block bodies of the fuse blocks. Thus, the electric distribution box is assembled. The electric distribution box supplies electric power, supplied from the power source or the like, to the various electronic equipments, mounted on the automobile, via the fuses and the wires of the wire harnesses.

In the electric distribution box, the two fuse blocks are connected together in such a manner that their longitudinal axes are disposed generally on the common line (that is, disposed linearly). Therefore, the length of the combined (pair of) fuse blocks becomes long, so that a space in which the pair of fuse blocks can be located has tended to be limited. Namely, the installation of the electric distribution box has tended to affect the arrangement of other equipments of the automobile, or the position in which the electric distribution box is installed has tended to be limited (Namely, the degree of freedom of installation of the electric distribution box has tended to be decreased.)

### SUMMARY OF THE INVENTION

It is therefore an object of this invention to provide an electric distribution box which is provided with at least one pair of cassette blocks, and can be enhanced in degree of freedom of installation thereof.

In order to achieve the above object, according to the present invention, there is provided an electric distribution box, comprising:

a first cassette block that includes a flat face having a first long side and a second short side, and provided with a first electric parts;

a second cassette block that includes a flat face having a second long side and a second short side, and provided with a second electric parts; and

a bus bar that connects a terminal of the first electric parts to a terminal of the second electric parts,

wherein the first cassette block and the second cassette block are arranged so that the first long side of the first cassette block is disposed in parallel and opposed to the second long side of the second cassette block; and

wherein the bus bar is disposed along outer surfaces of the first and second cassette blocks.

Preferably, the electric distribution box further includes a box body that has a mounting hole for receiving the first and second cassette blocks. The box body includes a rib having opposite ends respectively connected to opposed inner wall surfaces of the mounting hole of box body. The rib is disposed between the first cassette block and the second cassette block received in the box body.

Preferably, an insulating rib is formed on at least one of the first and second cassette blocks. The insulating rib electrically insulates wire harnesses, attached to the first and second cassette blocks respectively, from each other.

In the electric distribution box, the long sides of the cassette blocks are disposed in superimposed relation to each other, and therefore the longitudinal length of the combined cassette blocks can be prevented from unnecessarily increasing.

In the electric distribution box, the rib is formed on and extends between the opposed inner wall surfaces of the mounting hole, and therefore the rigidity of the box body can be prevented from being lowered.

And besides, the rib is disposed between the pair of cassette blocks, and therefore the rib will not prevent the mounting of the cassette blocks.

In the electric distribution box, there is provided the insulating rib, and therefore the electrical short-circuiting between the wire harnesses can be prevented.

As described above, the longitudinal length of the combined cassette blocks are prevented from unnecessarily increasing, and this prevents a space, in which the pair of cassette blocks can be located, from being limited. Namely, the installation of the electric distribution box is prevented from affecting the arrangement of other equipments of an automobile, and also the position in which the electric distribution box is installed will not be limited. Therefore, the degree of freedom of installation of the electric distribution box can be enhanced.

Furthermore, since the bus bar is disposed along the outer surfaces of the cassette blocks, the area of exposing of the bus bar to the exterior of the cassette blocks increases. Therefore, heat, generated by electric current flowing through the electric parts, can be radiated via the bus bar. Therefore, the temperature of the electric distribution box can be prevented from excessively rising.

In the invention, since the rigidity of the box body can be prevented from being lowered, the box body can be prevented from being distorted. And besides, since the rib is disposed between the pair of cassette blocks, the rib will not prevent the mounting of the cassette blocks. Therefore, in addition to an advantage that the degree of freedom of installation of the electric distribution box can be enhanced, the cassette blocks can be easily and positively mounted in the box body.

In the invention, the electrical short-circuiting between the wire harnesses can be prevented, and therefore the wire harnesses can be positively connected to the various electric parts, mounted on the box body, in desired patterns.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a perspective view showing an important portion of one preferred embodiment of an electric distribution box of the present invention;

FIG. 2 is a plan view of the electric distribution box of FIG. 1;

FIG. 3 is a cross-sectional view taken along the line III-III of FIG. 2;

FIG. 4 is an exploded, perspective view of an important portion of the electric distribution box of FIG. 1;

FIG. 5 is a perspective view showing a condition in which fuse blocks of the electric distribution box of FIG. 1 are combined together;

FIG. 6 is a perspective view showing a condition in which a bus bar is mounted on the combined fuse blocks of FIG. 5; and

FIG. 7 is a perspective view showing a condition in which the combined fuse blocks of FIG. 6 is mounted in a box body.

### DETAILED DESCRIPTION OF THE PREFERRED EMBODIMENTS

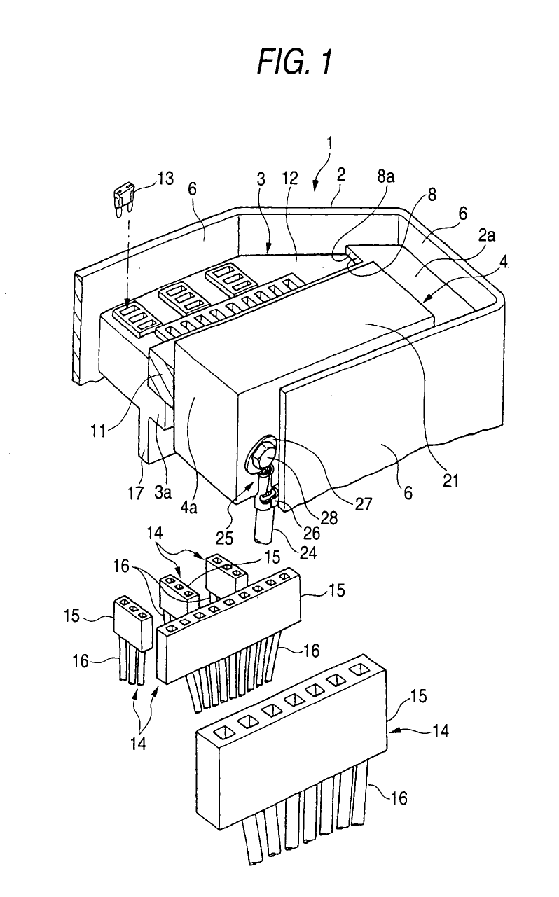

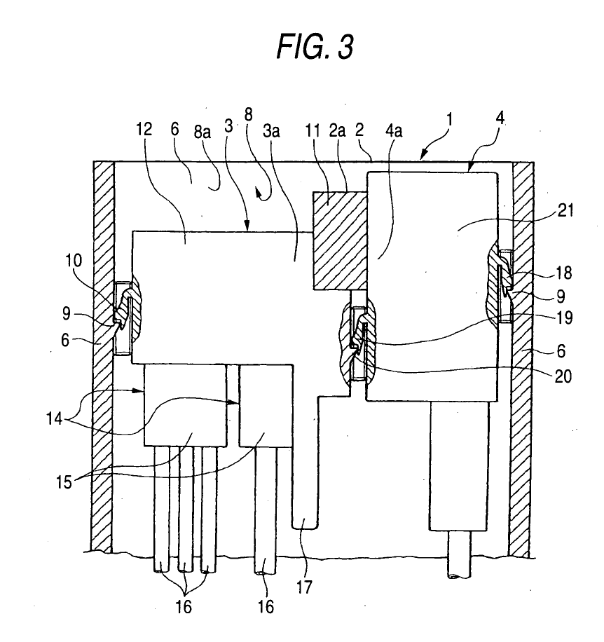

One preferred embodiment of an electric distribution box of the present invention will now be described with reference to FIGS. 1 to 7.

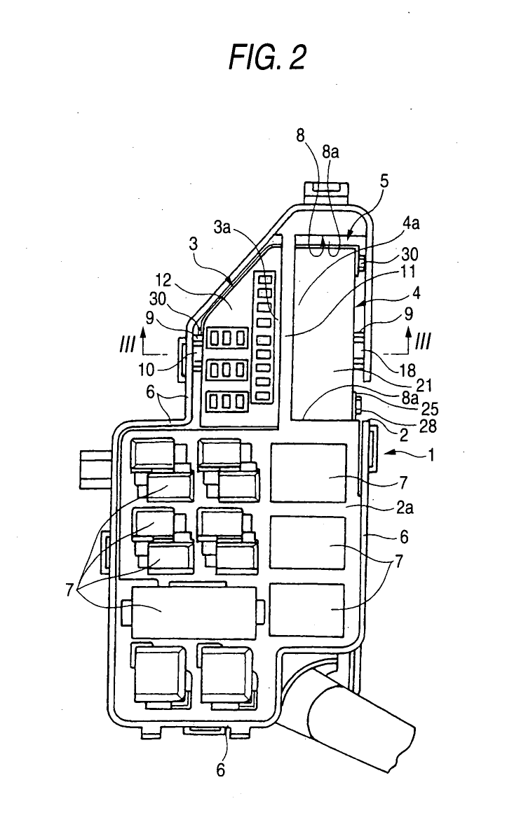

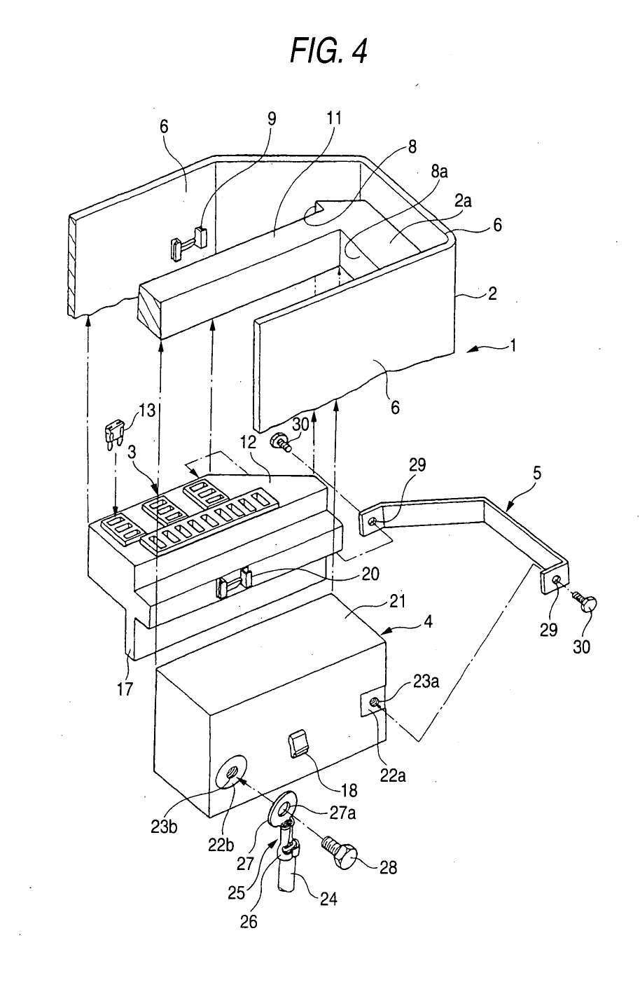

The electric distribution box 1 of this embodiment, shown in FIG. 1, is mounted on an automobile serving as a mobile body. As shown in FIGS. 1 to 4, the electric distribution box 1 comprises a box body 2, a fuse block 3 serving as a cassette block, a multi-fuse block 4 serving as a cassette block, wiring boards (not shown), a bus bar 5 (shown in FIGS. 2 and 4).

The box body 2 is made of an insulative synthetic resin, and is molded by a well known injection molding method. The box body 2 is formed into a generally tubular shape (box-shape) by a plurality of outer walls 6.

A plurality of electric parts such as relays 7 are mounted on an upper surface 2a (disposed at the upper side in FIG. 1) of the box body 2.

Connectors of wire harnesses (not shown), installed on the automobile, are fitted to a bottom surface (disposed at the lower side in FIG. 1) of the box body 2. Each of the wire harnesses comprises a plurality of wires, the connector mounted at distal ends of the wires, and an electronic equipment-connecting connector (not shown). The connectors are fitted to the bottom surface of the box body 2. In the present invention, the upper surface (2a) side of the box body 2 is referred to as the upper side, and the bottom surface side of the box body 2 is referred to as the lower side. The electronic equipment-connecting connectors are fitted respectively to connectors of various electronic equipments mounted on the automobile.

The box body 2 has a mounting hole 8 formed therein. The mounting hole 8 is formed in one longitudinal end portion of the box body 2. The mounting hole 8 is defined by a space surrounded by the plurality of outer walls 6 forming the box body 2. Opposite ends (upper and lower ends in FIGS. 1, 3 and 4) of the mounting hole 8 are open. Therefore, the box body 2 is formed into a generally tubular shape (tubular frame-shape). A plurality of retaining reception portions 9 for retaining engagement with respective retaining portions 10 and 18 (described later) of the fuse blocks 3 and 4 are formed on inner wall surfaces 8 of the mounting hole 8 of the box body 2.

A rib 11 is formed within the mounting hole 8. The rib 11 is in the form of a linearly-extending bar, and opposite ends of this rib are integrally connected respectively to the opposed inner wall surfaces 8a of the mounting hole 8. A longitudinal axis of the rib 11 is parallel to the longitudinal axis of the box body 2. The rib 11 is formed on edge portions of the inner wall surfaces 8 disposed adjacent to the upper surface 2a. When the pair of fuse blocks 3 and 4 are mounted in the box body 2, the rib 11 is disposed between the pair of fuse blocks 3 and 4. In the present specification, this is expressed as follows. The rib 11 is disposed in such a position as to be interposed between the pair of fuse blocks 3 and 4.

As shown in FIG. 1, the fuse block 3 comprises a box-like block body 12, and a plurality of fuses (electric parts) 13. The block body 12 is made of an insulative synthetic resin, and is molded by a well known injection molding method. The block body 12 has a pentagonal shape when viewed from the top. The plane shape of the block body 12 is such that its width in one direction is longer than its width in another direction perpendicular to the one direction.

The mounting hole 8 is divided into two spaces by the rib 11, and the block body 12 is received in one of the two spaces. When the block body 12 is received in this space, the longitudinal axis of the block body 12 is disposed parallel to the longitudinal axis of the box body 2. The retaining portion 10 for retaining engagement with the retaining reception portion 9 is formed on an outer wall of the block body 12 of the fuse block 3. The block body 12, that is, the fuse block 3, is received in the mounting hole 8, and the retaining portion 10 is retainingly engaged with the retaining reception portion 9, and thus the fuse block 3 is mounted in the box body 2. Connectors 15 of wire harnesses 14 are fitted to a lower surface (FIG. 1) of the block body 12.

Each wire harness 14 comprises a plurality of wires 16, the connector 15 mounted at distal ends of the wires 16, and the electronic equipment-connecting connector (not shown). The connectors 15 are fitted to the lower surface of the block body 12. The electronic equipment-connecting connectors are connected to connectors of the various electronic equipments mounted on the automobile.

A nut, connected to one terminal of one of the plurality of fuses 13 (not shown), is embedded in the outer wall of the block body 12 of the fuse block 3. An insulating rib 17 (shown in FIGS. 1, 3 and 4) is formed integrally with the block body 12 of the fuse block 3.

The insulating rib 17 is formed at an edge portion of the block body 12 (of the fuse block 3) disposed close to a block body 21 of the multi-fuse block 4. The insulating rib 17 is formed into a flat plate-like shape, and projects outwardly (that is, downwardly in FIG. 1) from the lower surface of the block body 12 to which the connector s15 of the wire harnesses 14 is fitted. The insulating rib 17 is disposed between the wire harnesses 14, attached to the fuse block 3, and the wire harnesses 14 and a wire (or cable) 24 (having an LA terminal 25) attached to the multi-fuse block 4, and electrically insulates the former wire harnesses 14 from the latter wire harnesses 14 and the wire 24.

The fuses 13 are attached to the block body 12, and thus are mounted on the fuse block 3.

The multi-fuse block 4 comprises the box-like block body 21, and a plurality of fuses (electric parts) (not shown). The block body 21 is made of an insulative synthetic resin, and is molded by a well known injection molding method. The block body 21 has a rectangular shape when viewed from the top. The plane shape of the block body, 21 is such that its width in one direction is longer than its width in another direction perpendicular to the one direction.

The block body 21 is received in the other of the two spaces of the mounting hole 8 separated from each other by the rib 11. When the block body 21 is received in this space, the longitudinal axis of the block body 21 is disposed parallel to the longitudinal axis of the box body 2. The retaining portion 18 for retaining engagement with the retaining reception portion 9 is formed on an outer wall of the block body 21 of the multi-fuse block 4.

The block body 21, that is, the multi-fuse block 4, is received in the mounting hole 8, and the retaining portion 18 is retainingly engaged with the retaining reception portion 9, and thus the multi-fuse block 4 is mounted in the box body 2. The connector 15 of the wire harness 14 is fitted to a lower surface (FIG. 1) of the block body 21. This wire harness 14 is generally identical in construction to the above-mentioned wire harnesses 14, and therefore its corresponding portions are designated by identical reference numerals, respectively, and explanation thereof will be omitted.

A nut, connected to one terminal of one of the plurality of fuses (not shown), is embedded in each of the outer walls of the block body 21 provided respectively at the longitudinally-opposite end portions thereof.

The fuses are received in the block body 21, and thus are mounted in the multi-fuse block 4.

The fuse block 3 and the multi-fuse block 4 are received in the box body 2 in such a manner that the longitudinal axes of the two blocks 3 and 4 are disposed parallel to the longitudinal axis of the box body 2, and therefore the fuse block 3 and the multi-fuse block 4 are disposed parallel to each other. Namely, the fuse block 3 and the multi-fuse block 4 are arranged in such a manner that their long sides 3a and 4a are disposed in superimposed relation to each other. A retaining portion 19 and a retaining reception portion 20, which can be retainingly engaged with each other, are formed respectively on the long sides 4a and 3a which are to be superimposed together. In the illustrated embodiment, the retaining reception portion 20 is formed on the fuse block 3, and the retaining portion 19 is formed on the multi-fuse block 4.

The wiring boards are received in the box body 2, the block body 12 of the fuse block 3 and the block body 21 of the multi-fuse block 4, respectively. Each wiring board includes the electrically-conductive bus bars, and insulating plates. Each bus bar is obtained by applying a pressing operation (such as a blanking operation) to an electrically-conductive metal sheet. There are provided the plurality of bus bars. The plurality of bus bars are stacked together. Each insulating plate is provided between the stacked bus bars, and prevents the bus bars from being electrically connected together (that is, short-circuited) at unintended portions thereof, and also serves to locate the bus bars in their proper positions.

In the wiring board received in the box body 2, the bus bars electrically connect the wires of the wire harnesses to the electric parts such as the relays 7 (mounted on the upper surface 2a) in a predetermined pattern.

In the wiring board received in the block body 12 of the fuse block 3, the bus bars electrically connect the wires 16 of the wire harnesses 14 to the fuses 13 in a predetermined pattern. Further, in the wiring board received in the block body 12 of the fuse block 3, the bus bar electrically connects one terminals of all of the fuses 13 (mounted at the block body 12 of the fuse block 3) together. A portion of the bus bar of the wiring board (received in the block body 12 of the fuse block 3), which electrically connects the one terminals of all of the fuses 13 together, is superposed on the above-mentioned nut embedded in the block body 12, and is exposed to the outer surface of the block body 12. A hole is formed in the exposed portion of the bus bar, and is in communication with a screw hole of the nut.

In the wiring board received in the block body 21 of the multi-fuse block 4, the bus bars electrically connect the wires 16 of the wire harness 14 to the fuses received in the block body 21 in a predetermined pattern. Further, in the wiring board received in the block body 21 of the multi-fuse block 4, the bus bar electrically connects one terminals of all of the fuses (mounted in the block body 21 of the multi-fuse block 4) together.

A portion 22a (shown in FIG. 4) of the bus bar of the wiring board (received in the block body 21 of the multi-fuse block 4), which electrically connects the one terminals of all of the fuses together, is superposed on one of the above-mentioned nuts embedded in the block body 21, and is exposed to the outer surface of the block body 21. Another portion 22b (shown in FIG. 4) of the bus bar of the wiring board is superposed on the other nut embedded in the block body 21, and is exposed to the outer surface of the block body 21. Holes 23a and 23b are formed respectively in the exposed portions 22a and 22b of the bus bar, and are in communication with screw holes of the above nuts, respectively.

The LA terminal (metal terminal) 25 is mounted on a distal end portion of the wire 24 connected to a power source such as a battery, and this LA terminal 25 is connected to the other portion 22b (which is disposed at the near side in FIG. 4) of the bus bar. The wire 24 is a so-called sheathed wire comprising an electrically-conductive core wire, and an insulative sheath covering this core wire.

The LA terminal 25 is formed by a relatively-thick metal sheet, and includes a wire connection portion 26 fixedly secured to the distal end portion of the wire 24 by press-clamping or the like, and a flat plate-like electrical contact portion 27 having a bolt passage hole 27a, the wire connection portion 26 and the electrical contact portion 27 being formed integrally with each other. The electrical contact portion 27 is superposed on the above-mentioned bus bar, and is fixedly secured to the multi-fuse block 4 by a bolt 28 passing through the bolt passage hole 27a and the hole 23b and threaded into the nut. The wire 24, having the LA terminal 25 mounted thereon, supplies electric power from the power source to the fuses of the multi-fuse block 4. The LA terminal 25 and the wire 24 (on which the LA terminal 25 is mounted) jointly form the wire harness recited in the present specification.

The bus bar 5 is formed by a relatively-thick metal sheet. The bus bar 5 is bent into a shape conforming to the contour defined by the outer surfaces of those portions of the fuse blocks 3 and 4 extending from the portion 22a(disposed at the far side in FIG. 4) of the bus bar of the multi-fuse block 4 to the exposed portion of the bus bar of the fuse block 3 exposed to the outer surface thereof. Holes 29 for communicating respectively with the hole 23a in the portion 22a of the bus bar and the hole in the exposed portion of the bus bar of the fuse block 3 are formed respectively in the opposite end portions of the bus bar 5. The longitudinally-opposite end portions of the bus bar 5 are superposed respectively on the portion 22a of the bus bar and the exposed portion of the bus bar of the fuse block 3, and bolts 30 pass respectively through the hole 29 and the hole in the exposed portion of the bus bar of the fuse block 3, and are threaded into the respective nuts, and by doing so, the bus bar 5 is mounted on the fuse blocks 3 and 4. Thus, the bus bar 5 connects one terminal of one of the fuses 13 of the fuse block 3 to one terminal of one of the fuses of the multi-fuse block 4.

As a result, the bus bar 5 is disposed along the outer surfaces of the fuse blocks 3 and 4 since the bus bar 5 is bent into the shape conforming to the contour defined by the outer surfaces of those portions of the fuse blocks 3 and 4 extending from the portion 22a (disposed at the far side in FIG. 4) of the bus bar of the multi-fuse block 4 to the exposed portion of the bus bar of the fuse block 3 exposed to the outer surface thereof.

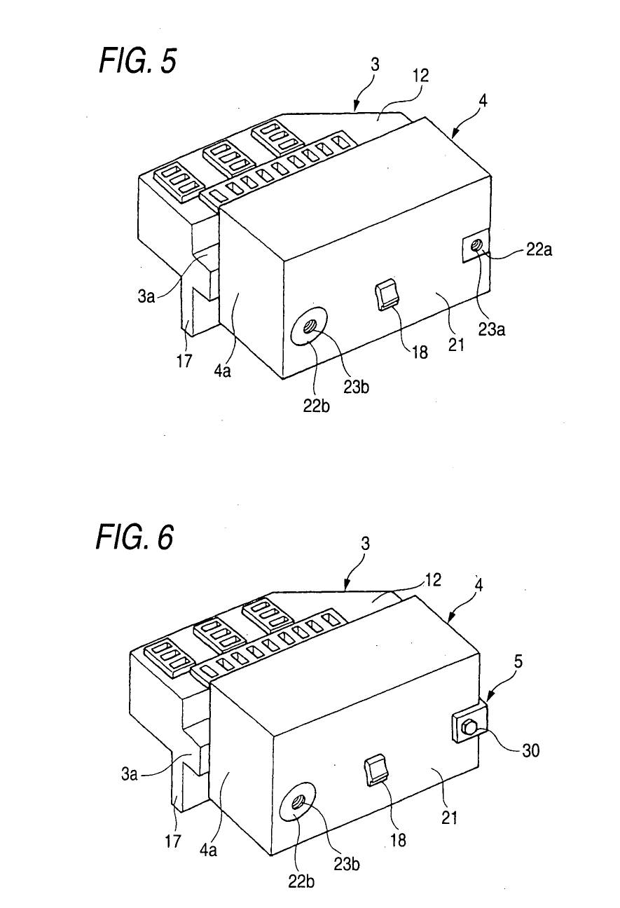

The above electric distribution box 1 is assembled in the following manner. First, the wiring board is received in the box body 2, and the wiring board is received in the block body 12 of the fuse block 3. Then, the retaining portion 19 of the multi-fuse block 4 is retainingly engaged with the retaining reception portion 20 of the fuse block 3, thereby fixing the fuse block 3 and the multi-fuse block 4 to each other in such a manner that their long sides 3a and 4a are superimposed together, as shown in FIG. 5. Then, the opposite end portions of the bus bar 5 are superposed respectively on the portion 22a of the bus bar and the exposed portion of the bus bar of the fuse block 3, and one of the bolts 30 is passed through the holes 29 and 23a, and is threaded into the nut, while the other bolt 30 is passed through the hole 29 and the hole in the exposed portion of the bus bar of the fuse block 3, and is threaded into the nut, as shown in FIG. 6. By doing so, the bus bar 5 is mounted on the fuse blocks 3 and 4, and is disposed along the outer surfaces of the fuse blocks 3 and 4.

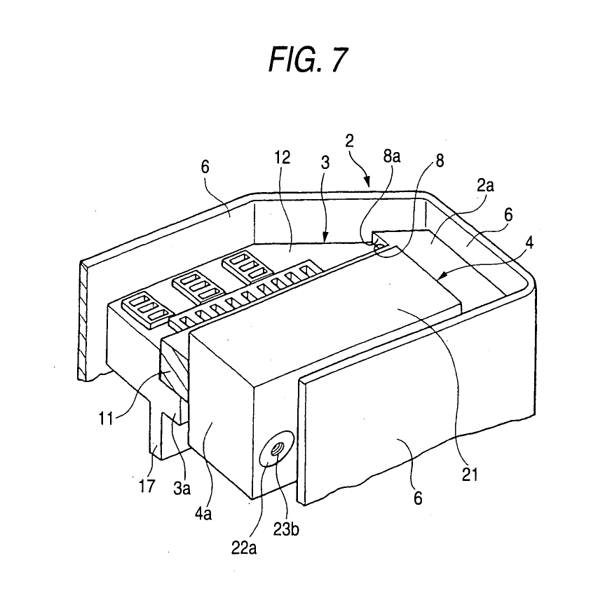

Then, the fuse blocks 3 and 4, thus combined together, are inserted into the mounting hole 8 from the bottom side. The retaining portions 10 and 18 of the fuse blocks 3 and 4 are retainingly engaged with the retaining reception portions 9 of the box body 2, respectively, thereby mounting the fuse blocks 3 and 4 in the box body 2, as shown in FIG. 7. Then, the desired fuses 13 are mounted on the fuse block 3, and the relays 7 and so on are mounted on the box body 2. Further, the LA terminal 25, mounted on the distal end of the wire 24, is connected to the other portion 22b of the bus bar, and the connectors 15 of the wire harnesses 14 are attached to the bottoms of the fuse blocks 3 and 4 and box body 2.

The electric distribution box 1 supplies electric power, supplied from the wire 24, to the various electronic equipments via the fuses 13 and so on.

In this embodiment, the long sides 3a and 4a of the fuse block 3 and multi-fuse block 4 (which serve as the cassette blocks) are disposed in superimposed relation to each other, and therefore the longitudinal length of the combined fuse blocks 3 and 4 can be prevented from unnecessarily increasing. This prevents a space, in which the pair of fuse blocks 3 and 4 can located, from being limited. Namely, the installation of the electric distribution box 1 is prevented from affecting the arrangement of other equipments of the automobile, and also the position in which the electric distribution box 1 is installed will not be limited. Therefore, the degree of freedom of installation of the electric distribution box 1 can be enhanced.

And besides, since the bus bar 5 is disposed along the outer surfaces of the fuse blocks 3 and 4, the area of exposing of the bus bar 5 to the exterior of the fuse blocks 3 and 4 increases. Therefore, heat, generated by electric current flowing through the fuses 13 and so on, can be radiated via the bus bar 5. Therefore, the temperature of the electric distribution box 1 can be prevented from excessively rising.

The rib 11 is formed on and extends between the opposed inner wall surfaces 8a of the mounting hole 8, and therefore the rigidity of the box body 2 can be prevented from being lowered. Therefore, the box body 2 can be prevented from being distorted.

Furthermore, since the rib 11 is disposed between the pair of fuse blocks 3 and 4, the rib 11 will not prevent the mounting of the fuse blocks 3 and 4. Therefore, in addition to an advantage that the degree of freedom of installation of the electric distribution box 1 can be enhanced, the fuse blocks 3 and 4 can be easily and positively mounted in the box body 2.

Furthermore, the insulating rib 17 is provided at the fuse block 3, and therefore the electrical short-circuiting between the wire harnesses 14 and the wire 24 with the LA terminal 25 can be prevented. Therefore, the wire harnesses 14 and the wire 24 with the LA terminal 25 can be positively connected to the various electric parts, including the fuses 13, in desired patterns.

The above embodiment is merely a representative one, and the present invention is not limited to the above embodiment. Namely, various modifications can be made without departing from the subject matter of the invention.

Namely, in the above embodiment, the insulating rib 17 is formed on the block body 12 of the fuse block 3. However, the insulating rib 17 can be formed on the bock body 21 of the multi-fuse block 4.

Also, in the above embodiment, the fuse blocks 3 and 4 at which the fuses 13 are mounted are used as the cassette blocks. In the invention, however, other electric parts (such as relays and fusible links) than the fuses 13 can be mounted at the cassette blocks.

Although the invention has been illustrated and described for the particular preferred embodiments, it is apparent to a person skilled in the art that various changes and modifications can be made on the basis of the teachings of the invention. It is apparent that such changes and modifications are within the spirit, scope, and intention of the invention as defined by the appended claims.

The present application is based on Japan Patent Application No. 2005-141583 filed on May 13, 2005, the contents of which are incorporated herein for reference.

What is claimed is:

1. An electric distribution box, comprising:
a first cassette block that includes a flat face having a first long side and a second short side, and provided with a first electric parts;
a second cassette block that includes a flat face having a second long side and a second short side, and provided with a second electric parts; and
a bus bar that connects a terminal of the first electric parts to a terminal of the second electric parts,
wherein the first cassette block and the second cassette block are arranged so that the first long side of the first cassette block is disposed in parallel and opposed to the second long side of the second cassette block; and
wherein the bus bar is disposed along outer surfaces of the first and second cassette blocks.

2. The electric distribution box according to claim 1, further comprising a box body that has a mounting hole for receiving the first and second cassette blocks,
wherein the box body includes a rib having opposite ends respectively connected to opposed inner wall surfaces of the mounting hole of box body; and
wherein the rib is disposed between the first cassette block and the second cassette block received in the box body.

3. The electric distribution box according to claim 1, wherein an insulating rib is formed on at least one of the first and second cassette blocks; and
wherein the insulating rib electrically insulates wire harnesses, attached to the first and second cassette blocks respectively, from each other.
